(19) United States
(12) Patent Application Publication
(10) Pub. No.: US 2026/0212943 A1
(43) Pub. Date: Jul. 23, 2026

(54) MEMORY DEVICE INCLUDING DIGITAL PHASE-LOCKED LOOP MOUNTED IN PHYSICAL INTERFACE, AND SEMICONDUCTOR PACKAGE

(71) Applicant: Samsung Electronics Co., Ltd., Suwon-si (KR)

(72) Inventors: Yongsun Lee, Suwon-si (KR); Daihyun Lim, Suwon-si (KR); Insung Kim, Suwon-si (KR); Sungho Lee, Suwon-si (KR)

(21) Appl. No.: 19/299,463

(22) Filed: Aug. 14, 2025

(30) Foreign Application Priority Data
Jan. 22, 2025 (KR) 10-2025-0009821

(51) Int. Cl. G11C 29/12; H03L 7/099

(52) U.S. Cl. CPC G11C 29/12015; G11C 29/1201; H03L 7/0991; H03L 2207/50

(57) ABSTRACT

A memory device has a physical interface (PHY) including a digital phase-locked loop (DPLL), and a semiconductor package. The memory device includes a base die and at least one core die. The base die includes a direct access (DA) region configured to receive a test clock signal from an outer environment via a pad and a PHY including at least one DPLL configured to generate an output clock signal by changing capacitance of a capacitor bank of a digitally-controlled oscillator (DCO) based on a pulse width modulation (PWM) signal according to a phase difference between the test clock signal and a feedback signal.

### CROSS-REFERENCE TO RELATED APPLICATIONS

This application claims priority under 35 U.S.C. § 119(a) to Korean Patent Application No. 10-2025-0009821, filed on Jan. 22, 2025, in the Korean Intellectual Property Office, the disclosure of which is incorporated by reference herein in its entirety.

### TECHNICAL FIELD

The present disclosure relates to electronic devices, and more particularly, to memory devices and semiconductor packages.

### BACKGROUND

A plurality of dies may be stacked on one another to increase the degree of integration of a memory device. A memory device having a three-dimensional structure may provide higher capacity and higher bandwidth than a general memory device. The memory device that provides the high capacity and high bandwidth may be referred to as high bandwidth memory (HBM).

In order to examine performance of the HBM, tests of the HBM may be conducted on a wafer before the HBM is packaged with a processor, a board, etc. For example, a test may be performed to examine signal input/output performance in a physical interface (PHY) of the HBM. In this case, a clock signal for the test may be used, but due to limitations of testers or wafer probes capable of generating clock signals, a clock signal cannot be directly input with a high frequency, corresponding to the data rate of the HBM, from outside to a direct access (DA) region of the HBM. Therefore, the HBM may include a phase-locked loop (PLL), and the PLL may convert a low-frequency clock signal for the test, which is input from the outside, into a high-frequency clock signal. For example, the PLL may include an analog PLL (APLL).

Since the APLL has a relatively large area, the APLL is located in the DA region of the HBM. The physical distance between the DA region and the PHY is relatively large, and thus, the clock signal for the test passes through a plurality of buffer stages to reach the PHY from the DA. A change in clock skew or duty can increase while the clock signal for the test is transmitted from the DA region to the PHY, which degrades jitter performance of the clock signal. Therefore, since the clock signal that has reached the PHY has degraded, it may be difficult to conduct a test for examining the signal input/output (I/O) performance of the PHY.

Due to demands for enhanced high-speed HBM, the period of the clock signal is getting shorter. As the period of the clock signal decreases, a larger portion of the clock signal is occupied by jitter, which exacerbates the limitations stated above. In addition, in order to further increase I/O throughput of the HBM, the number of pins of the HBM increases, the PHY becomes larger, and the physical distance between the PHY and the DA region also increases, which further exacerbates the limitations stated above.

### SUMMARY

Some aspects of the present disclosure provide a memory device that has a physical interface (PHY) including a small-area digital phase-locked loop. Some aspects of the present disclosure provide a semiconductor package.

According to an aspect of the present disclosure, there is provided a memory device including a base die and at least one core die. The base die includes a direct access (DA) region configured to receive a test clock signal from an outer environment via a pad and a PHY including at least one digital phase-locked loop (DPLL) configured to generate an output clock signal by changing capacitance of a capacitor bank of a digitally-controlled oscillator (DCO) based on a pulse width modulation (PWM) signal according to a phase difference between the test clock signal and a feedback signal.

According to another aspect of the present disclosure, there is provided a memory device including a base die and at least one core die. The base die includes a DA region configured to receive a test clock signal from an outer environment via a pad and a PHY including at least one DPLL configured to generate an output clock signal based on the test clock signal. The at least one DPLL includes a time-to-digital converter (TDC) configured to convert a phase difference between the test clock signal and a feedback signal into a digital signal, a digital loop filter (DLF) configured to, based on the digital signal, generate a digital code that adjusts a duty ratio for a first period corresponding to a cycle of the feedback signal, a pulse width modulation (PWM) configured to, based on the digital code, generate a PWM signal having the duty ratio, a DCO configured to adjust an output frequency of the output clock signal by changing capacitance of a capacitor bank based on the PWM signal, and a divider configured to generate the feedback signal by dividing the output clock signal.

According to another aspect of the present disclosure, there is provided a semiconductor package including a substrate, at least one memory device disposed on the substrate and including a base die and at least one core die, and a processing chip disposed on the substrate and configured to output a clock signal to the base die. The base die includes a PHY including at least one DPLL configured to generate an output clock signal by changing capacitance of a capacitor bank of a DCO based on a pulse width modulation (PWM) signal according to a phase difference between the clock signal and a feedback signal and a through silicon via (TSV) region configured to communicate with the at least one core die.

### BRIEF DESCRIPTION OF THE DRAWINGS

FIG. 1 is a diagram illustrating a memory device according to an implementation.

FIG. 2 is a diagram showing an example in which a digital phase-locked loop (DPLL) is arranged in a physical interface (PHY) of a base die according to implementations.

FIG. 3 is a diagram illustrating first and second clock paths in the example of FIG. 2.

FIG. 4 is a diagram showing an example in which first and second DPLLs are arranged in a PHY of a base die according to implementations.

FIG. 5 is a diagram illustrating first and second clock paths in the example of FIG. 4.

FIG. 6 is a diagram showing an example in which first to fourth DPLLs are arranged in a PHY of a base die according to implementations.

FIG. 7 is a diagram showing an example in which a plurality of DPLLs are arranged in a PHY of a base die according to implementations.

FIG. 8 is a diagram showing an example in which one DPLL is arranged in one channel.

FIG. 9 is a diagram showing an example in which first and second DPLLs are arranged in one channel.

FIG. 10 is a diagram illustrating a testing operation according to implementations.

FIG. 11 is a block diagram of a DPLL according to implementations.

FIGS. 12 to 14 are diagrams showing examples of semiconductor packages according to implementations.

### DETAILED DESCRIPTION

Hereinafter, implementations are described in detail with reference to the accompanying drawings.

As used herein, the expressions for ordinal numbers, such as “first,” “second,” may modify various components, regardless of order and/or importance, and are only used to distinguish one component from other components and do not limit the components. For example, a first user device and a second user device may represent different user devices, regardless of the order or importance. For example, a first component may be referred to as a second component, and similarly, a second component may be referred to as a first component, without departing from the scope of the present disclosure.

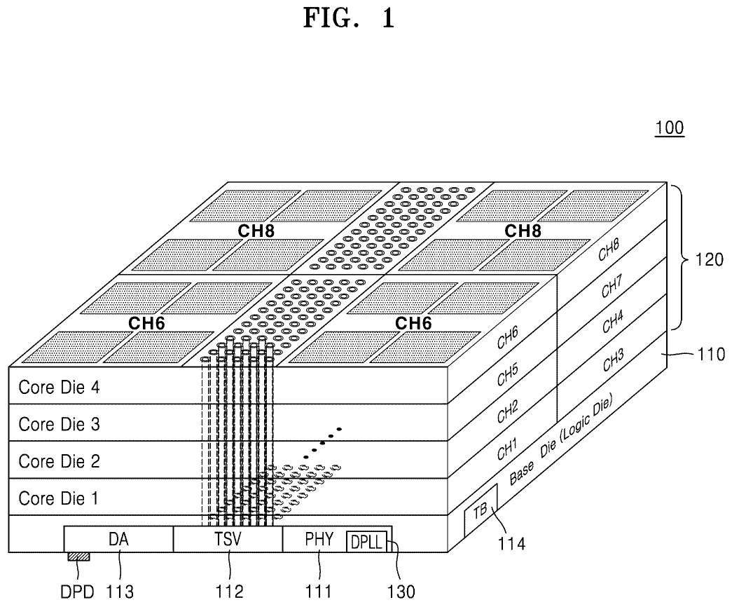

FIG. 1 is a diagram illustrating a memory device 100 according to an implementation.

Referring to FIG. 1, the memory device 100 may include a plurality of channels having independent interfaces, thereby achieving an increased bandwidth. That is, the memory device 100 may be configured as high bandwidth memory (HBM).

The memory device 100 may include a base die 110 and at least one core die 120 stacked on the base die 110. The base die may be referred to as a buffer die or a logic die. In FIG. 1, the memory device 100 includes four core dies (see Core Die 1, Core Die 2, Core Die 3, and Core Die 4 in FIG. 1), but the number of core dies may vary, depending on the version of the HBM, such as two, four, eight, or sixteen.

The base die 110 may include a physical interface (PHY) 111 (see PHY in FIG. 1), a through silicon via (TSV) region 112, and a direct access (DA) region 113.

The PHY 111 may include interface circuits that communicate with a processor that is external to the memory device 100 and operates as a host, and each of the interface circuits may receive a command, an address signal, a data signal, and a clock signal from the processor via buses arranged corresponding to channels. The buses may be formed separately for individual channels, or some of the buses may be shared by at least two channels.

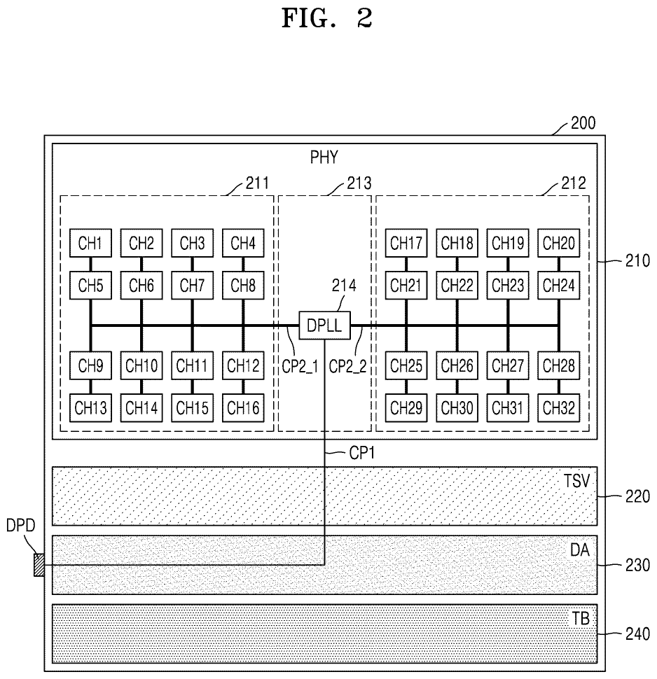

In an implementation, the PHY 111 may include at least one digital phase-locked loop (DPLL) 130. At least one DPLL 130 may receive a reference clock signal and generate an output clock signal required by the memory device 100 based on the reference clock signal. For example, a test clock signal provided to the DA region 113 via a pad DPD may be input to at least one DPLL 130 as a reference clock signal. For example, the clock signal provided from the processor via the PHY 111 may be input to at the least one DPLL 130 as the reference clock signal. Various examples in which the at least one DPLL 130 is placed in the PHY 111 are described below with reference to FIGS. 2, 4, and 6 to 9.

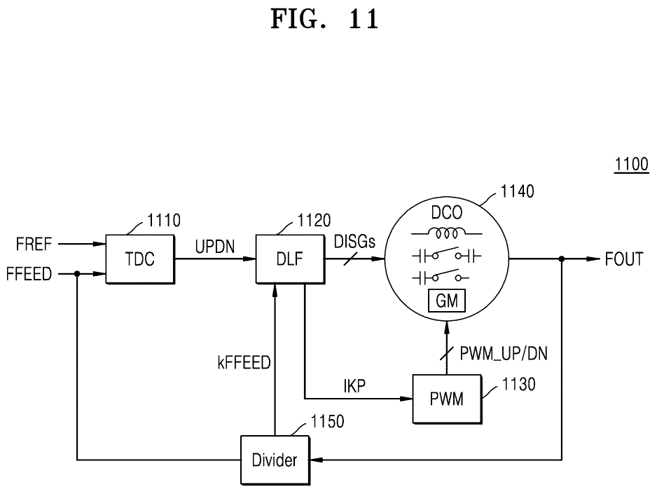

In an implementation, the at least one DPLL 130 may be configured to generate an output clock signal, by changing capacitance of a capacitor bank of a digitally-controlled oscillator (DCO) based on a pulse width modulation (PWM) signal according to the phase difference between the reference clock signal and a feedback signal. A specific example of the at least one DPLL 130 is described below with reference to FIG. 11.

The TSV region 112 may be configured to communicate with the at least one core die 120. For example, the TSV region 112 may include a plurality of TSVs that pass through the at least one core die 120. The plurality of TSVs may be arranged corresponding to the channels (see CH1 to CH8 in FIG. 1). For example, a first core die (see Core Die 1 in FIG. 1) may include first and third channels (see CH1 and CH3 in FIG. 1), a second core die (see Core Die 2 in FIG. 1) may include second and fourth channels (see CH2 and CH4 in FIG. 1), and a third core die (see Core Die 3 in FIG. 1) may include fifth and seventh channels (see CH5 and CH7 in FIG. 1), and a fourth core die (see Core Die 4 in FIG. 1) may include sixth and eighth channels (see CH6 and CH8 in FIG. 1). When each channel has a bandwidth of 128 bits, the plurality of TSVs may include components for inputting and outputting 1024 bits of data. However, the configuration of the TSV region is not limited to the example described above.

The DA region 113 may be configured to, in a test mode for the memory device 100, communicate directly with an external tester via the pad DPD located on the outer surface of the memory device 100. A test logic circuit that performs various operations related to the test may be provided inside the base die 110. The various test signals generated by the tester may be provided to the at least one core die 120 via the DA region 113 and the TSV region 112.

Depending on the test mode, some of the various test signals generated by the tester may also be provided to the PHY 111 via the DA region 113. In an implementation, a test clock signal may be generated by a tester or a wafer probe, etc. and the test clock signal may be provided to the DA region 113 via the pad DPD. The test clock signal may include a clock signal used in the test mode. For example, the test clock signal may include a clock signal that is used to test the data I/O performance of the PHY 111 in a chip-on-wafer state (or in a wafer level) before the memory device 100 is packaged. The test clock signal may have a frequency that is relatively smaller than the frequency of the clock signal used for the operation of the memory device 100. Since the test clock signal is a low-frequency signal, a portion of the test clock signal, occupied by jitter, may be less than the case of a high-frequency signal.

The at least one core die 120 may each include two channels. Referring to FIG. 1, for example, the memory device 100 including the four core dies may have eight channels (see CH1 to CH8 in FIG. 1). Each of the channels may include a memory cell array, a peripheral circuit that controls a memory operation of the memory cell array, and the like.

When the DPLL 130 having a small area is included in the PHY 111, the physical distance of paths between the DPLL 130 and the PHY 111 may be reduced, and the complexity of the paths between the DPLL 130 and the PHY 111 may be simplified. Therefore, the quality (e.g., jitter) of the clock signal used for the test in the chip-on-wafer state may be improved.

In addition, when the quality of the clock signal used for the test in the chip-on-wafer state is improved, the test may be performed properly even for the memory device 100 having a high data rate.

FIG. 2 is a diagram showing an example in which a DPLL 214 is arranged in a PHY 210 of a base die 200 according to implementations. FIG. 2 may be a plan view of the base die 200.

Referring to FIG. 2, the base die 200 may correspond to the base die 110 of FIG. 1. The base die 200 may include a PHY 210, a TSV region 220, and a DA region 230. The PHY 210, the TSV region 220, and the DA region 230 may correspond to the PHY 111, the TSV region 112, and the DA region 113 of FIG. 1, respectively.

The PHY 210 may include at least one channel region and a peripheral region 213. In FIG. 2, the first and second channel regions 211 and 212 are configured as at least one channel region in the PHY 210, but the configuration of the channel regions is not limited to the example shown in FIG. 2. The number of channel regions may vary.

At least one channel region may include a plurality of channels. For example, when the base die 200 belongs to an HBM in a version of HBM3E or higher, the first channel region 211 may include 16 channels (see CH1 to CH16 in FIG. 2), and the second channel region 212 may include 16 channels (see CH17 to CH32 in FIG. 2). That is, the PHY 210 may include 32 channels (see CH1 to CH32 in FIG. 2). However, the configuration of the channels is not limited to the example described above, and the PHY 210 may include a number of channels less than 32 (e.g., 4, 8, 12, or 16) or may include a number of channels greater than 32. The 16 channels in each of the first and second channel regions 211 and 212 may be arranged symmetrically with respect to each other. Each of the 32 channels may be configured to communicate with an external processor and to receive an output clock signal from the DPLL 214. The first and second channel regions 211 and 212 may further include at least portions of second clock paths CP2_1 and CP2_2 that route 32 channels and the DPLL 214.

The peripheral region 213 may be a region other than the first and second channel regions 211 and 212 in the PHY 210, and may include the DPLL 214. The peripheral region 213 may further include a portion of a first clock path CP1 and at least portions of the second clock paths CP2_1 and CP2_2, which route the pad DPD and the peripheral region 213. The peripheral region 213 may further include signal lines, buses, or various function blocks for communicating with other regions (e.g., 220, 230, and/or 240) of the base die 200.

In an implementation, the test clock signal input via the pad DPD in the test mode may be input to the DPLL 214 via the first clock path CP1. The output clock signal output by the DPLL 214 may be input to the 32 channels via the second clock paths CP2_1 and CP2_2. The first clock path CP1 may have a first path length, and each of the second clock paths CP2_1 and CP2_2 may have a second path length. The path length may represent the length of the path that includes various signal lines, repeaters, and the like for routing the components. In an implementation, the first path length may be greater than the second path length.

The DA region 230 may include a portion of the first clock path CP1.

The base die 200 may further include a test block (TB) region 240. The TB region 240 may include a test control circuit, a test logic circuit, and the like for performing a test on the memory device 100 of FIG. 1. For example, the TB region 240 may include various other test circuits capable of performing a memory built-in self-test (MBIST), IEEE 1500, cell repair, a TSV logic scan, EXTEST TX/RX, and HBM reset. The TB region 240 may communicate with the DA region 230 in the test mode and transmit various signals used for the test to the DA region 230.

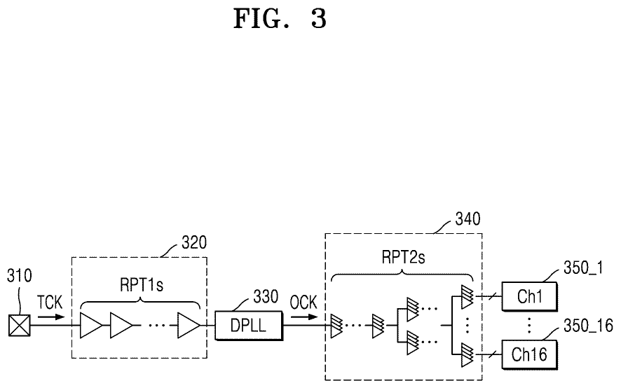

FIG. 3 is a diagram illustrating first and second clock paths 320 and 340 in the example of FIG. 2.

Referring to FIG. 3, a pad 310 may correspond to the pad DPD of FIGS. 1 and 2, the first clock path 320 may correspond to the first clock path CP1 of FIG. 2, a DPLL 330 may correspond to the DPLL 214 of FIG. 2, and the second clock path 340 may correspond to any of the second clock paths CP2_1 and CP2_2 of FIG. 2. In the example of FIG. 3, the second clock path 340 is assumed to be the second clock path CP2_1 of FIG. 2. In this case, 1st to 16th channels 350_1 to 350_16 may be channels in the first channel region 211 of FIG. 2.

The first clock path 320 may transmit a test clock signal TCK from the pad 310 to the DPLL 330. The first clock path 320 may include a first repeater group that constitutes a clock tree. The first repeater group may include a plurality of first repeaters RPT1s that are arranged in a line and connected to each other in series. A repeater according to the present disclosure may be configured to re-transmit the received signal. The repeater may be configured as a buffer, an inverter, or the like. The plurality of first repeaters RPT1s may be arranged at certain intervals. In an implementation, the test clock signal TCK transmitted via the first clock path 320 may be a relatively low-frequency signal compared to an output clock signal OCK, and thus, distances between the plurality of first repeaters RPT1s may be relatively large. The clock tree of the first clock path 320 may be formed as, for example, an H-tree, but the implementation is not limited thereto. Since the test clock signal TCK is a low-frequency signal, the test clock signal TCK may be transmitted as a single or differential signal. Accordingly, the power consumed by the plurality of first repeaters RPT1s may be relatively reduced, and the burden imposed on transmitting the test clock signal TCK may also be relatively reduced.

The DPLL 330 may generate the output clock signal OCK based on the test clock signal TCK.

The second clock path 340 may transmit the output clock signal OCK from the DPLL 330 to the 1st to 16th channels 350_1 to 350_16.

The second clock path 340 may include a second repeater group that constitutes a clock tree. The second repeater group may include a plurality of second repeaters RPT2s. Certain second repeaters RPT2s among the plurality of second repeaters RPT2s may be included in one sub-repeater group, and sub-repeater groups may be connected to each other in series. The number of second repeaters RPT2s connected to each other in parallel in each of the sub-repeater groups may be determined by the number of clock signals having different phases to generate the output clock signal OCK. For example, when the output clock signal OCK corresponds to four clock signals having different phases, the number of second repeaters RPT2s connected to each other in parallel in each of the sub-repeater groups may be four. However, the configuration of the repeaters is not limited to the example described above. The sub-repeater groups of the plurality of second repeaters RPT2s may be arranged at certain intervals. In an implementation, the output clock signal OCK transmitted via the second clock path 340 may be a relatively high-frequency signal compared to the test clock signal TCK, and thus, distances between the repeater groups of the plurality of second repeaters RPT2s may be relatively small.

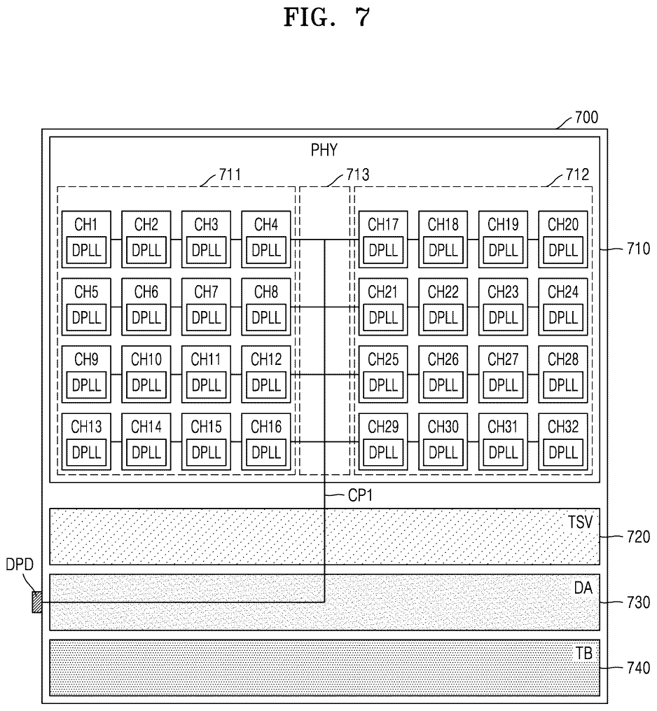

The second repeaters RPT2s of the second clock path 340 may also be included in each of the channels, which is described below with reference to FIGS. 7 to 9. The clock tree of the second clock path 340 may be formed as, for example, an H-tree, a fishbone, a mesh, and/or a combination thereof, but the implementation is not limited thereto.

In an implementation, the number of first repeaters RPT1s in the first repeater group may be less than the number of second repeaters RPT2s in the second repeater group. A first path length of the first clock path 320 may be greater than a second path length of the second clock path 340.

FIG. 3 shows one second clock path 340 routed to the 1st to 16th channels 350_1 to 350_16, but another second clock path routed to the channels of the second channel region 212 of FIG. 2 may be applied as described above.

When the DPLL 330 is included in the PHY 210, the clock tree of the second clock path 340 may be simplified, and the physical length of the second clock path 340 may be reduced. Accordingly, the clock signal used for the test in the chip-on-wafer state may be transmitted from the DA region 230 to the PHY 210 without degradation. During the test in the chip-on-wafer state, the output clock signal OCK may be distributed without degradation inside the PHY 210. Therefore, the performance of the test in the chip-on-wafer state may be improved.

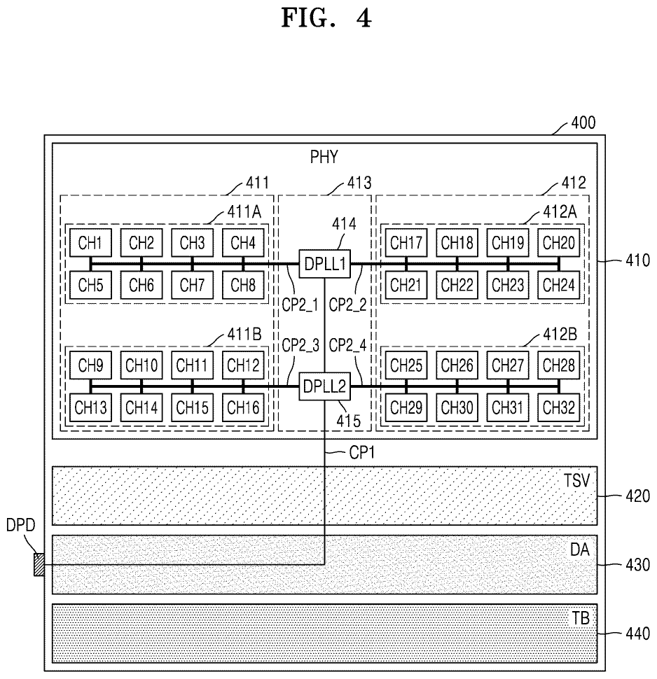

FIG. 4 is a diagram showing an example in which first and second DPLLs 414 and 415 are arranged in a PHY 410 of a base die 400 according to implementations. When describing an implementation of FIG. 4, repeated descriptions as those given above with reference to FIG. 2 are omitted.

Referring to FIG. 4, the base die 400 may include a PHY 410, a TSV region 420, a DA region 430, and a TB region 440. The PHY 410 may include at least one channel region (e.g., first and second channel regions 411 and 412) and a peripheral region 413. The first and second channel regions 411 and 412 may each include a certain number of channels, for example, 16 channels.

In an implementation, a plurality of channels, for example, 32 channels, may be classified into channel groups that include a predetermined number of channels. For example, the channels in each of the channel regions may be classified into channel groups (411A, 411B, 412A, and 412B), each of which includes eight channels as a single unit. For example, 1st to 8th channels of the first channel region 411 may be included in a first channel group 411A, 9th to 16th channels of the first channel region 411 may be included in a second channel group 411B, 17th to 24th channels of the second channel region 412 may be included in a first channel group 412A, and 25th to 32nd channels of the second channel region 412 may be included in a second channel group 412B.

In an implementation, the peripheral region 413 may include the first and second DPLLs 414 and 415. The first and second DPLLs 414 and 415 may be routed with the pad DPD via the first clock path CP1. In this case, the first clock path CP1 may constitute a clock tree to transmit the test clock signal TCK to each of the first and second DPLLs 414 and 415.

The first DPLL 414 may be routed and/or connected to the first channel group 411A of the first channel region 411 via a second clock path CP2_1. The first DPLL 414 may be routed and/or connected to the first channel group 412A of the second channel region 412 via a second clock path CP2_2.

The second DPLL 415 may be routed and/or connected to the second channel group 411B of the first channel region 411 via a second clock path CP2_3. The second DPLL 415 may be routed and/or connected to the second channel group 412B of the second channel region 412 via a second clock path CP2_4.

In an implementation, a first path length of the first clock path CP1 may be greater than a second path length of each of the second clock paths CP2_1, CP2_2, CP2_3, and CP2_4.

As described above, when the first and second DPLLs 414 and 415 are included in the PHY 410, local mismatch caused by intra-die variation (IDV) for individual channels is cancelled out.

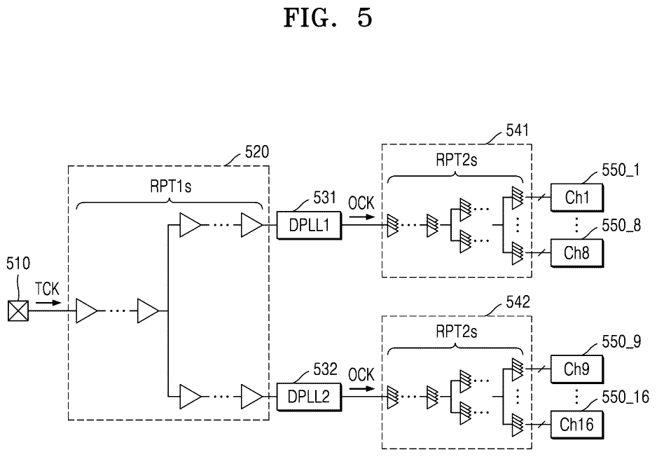

FIG. 5 is a diagram illustrating first and second clock paths 520, 541, and 542 in the example of FIG. 4. When describing an implementation of FIG. 5, repeated descriptions as those given above with reference to FIGS. 3 and 4 are omitted. In the example of FIG. 5, the second clock paths 541 and 542 are assumed to be the second clock paths CP2_1 and CP2_2 of FIG. 4.

Referring to FIG. 5, the first clock path 520 may include a plurality of first repeaters RPT1s that constitute a clock tree. The clock tree of the first clock path 520 may have at least one branch point to connect some of the plurality of first repeaters RPT1s to each other between a pad 510 and a first DPLL 531 and to connect the other plurality of first repeaters RPT1s to each other between the pad 510 and a second DPLL 532. In this case, the some of the plurality of first repeaters RPT1s on a path between the pad 510 and the first DPLL 531 may be connected to each other in series. The other plurality of first repeaters RPT1s on a path between the pad 510 and the second DPLL 532 may be connected to each other in series.

The second clock path 541 may be routed to the first DPLL 531 and 1st to 8th channels 550_1 to 550_8. The second clock path 542 may be routed to the second DPLL 532 and 9th to 16th channels 550_9 to 550_16. The plurality of second repeaters RPT2s in each of the second clock paths 541 and 542 are the same as described with reference to FIG. 3.

In an implementation, the number of first repeaters RPT1s in the first clock path 520 may be less than the number of second repeaters RPT2s in each of the second clock paths 541 and 542. A first path length of the path between the pad 510 and the first DPLL 531 and/or a first path length of the path between the pad 510 and the second DPLL 532 may be greater than a second path length of each of the second clock paths 541 and 542.

As described above, the clock signals used for the test in the chip-on-wafer state may be transmitted from the DA region 430 to the PHY 410 without degradation by reducing the physical length of the second clock paths 541 and 542 and simplifying the clock tree of the second clock paths 541 and 542. Accordingly, the performance of the test in the chip-on-wafer state may be improved.

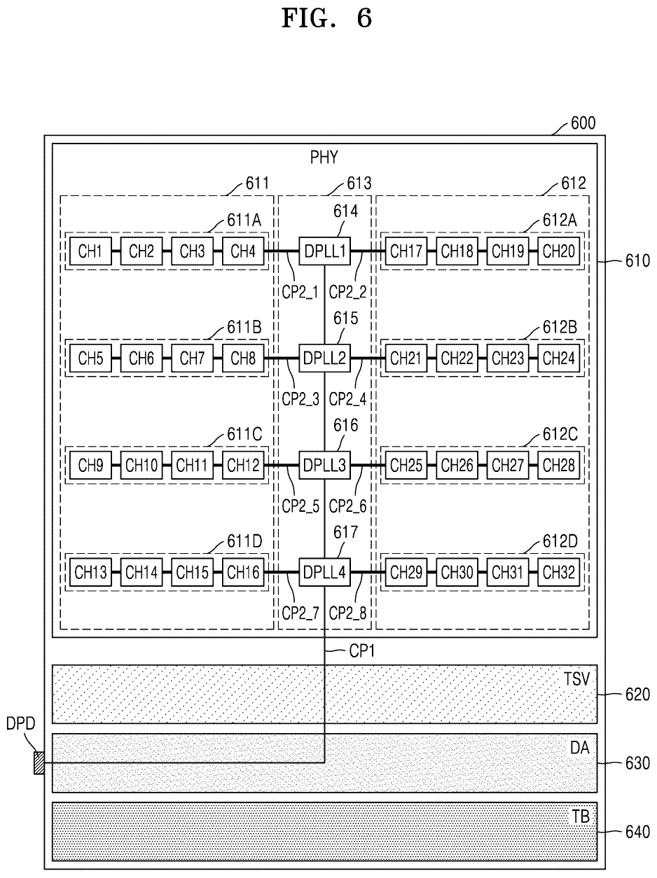

FIG. 6 is a diagram showing an example in which first to fourth DPLLs 614, 615, 616, and 617 are arranged in a PHY 610 of a base die 600 according to implementations. When describing an implementation of FIG. 6, repeated descriptions as those given above with reference to FIGS. 2 and 4 are omitted.

Referring to FIG. 6, the base die 600 may include the PHY 610, a TSV region 620, a DA region 630, and a TB region 640. The PHY 610 may include first and second channel regions 611 and 612 and a peripheral region 613. In FIG. 6, a plurality of channels, for example, 32 channels, may be grouped into units of four channels. 1st to 4th channels of the first channel region 611 may be included in a first channel group 611A, 5th to 8th channels of the first channel region 611 may be included in a second channel group 611B, 9th to 12th channels of the first channel region 611 may be included in a third channel group 611C, and 13th to 16th channels of the first channel region 611 may be included in a fourth channel group 611D. 17th to 32nd channels of the second channel region 612 may also be grouped into first to fourth channel groups 612A, 612B, 612C, and 612D, which is similar to the example described above. When the number of channels is greater than 32, the number of channels in each of the groups 611A, 611B, 611C, and 611D, 612A, 612B, 612C, and 612D may be set to various values.

In an implementation, the peripheral region 613 may include the first to fourth DPLLs 614, 615, 616, and 617. The first to fourth DPLLs 614, 615, 616, and 617 may be routed with the pad DPD via the first clock path CP1. In this case, the first clock path CP1 may form a clock tree having at least four branch points to transmit the test clock signal TCK to each of the first and second DPLLs 614 and 615.

The first DPLL 614 may be routed and/or connected to the first channel groups 611A and 612A via second clock paths CP2_1 and CP2_2. The second DPLL 615 may be routed and/or connected to the second channel groups 611B and 612B via second clock paths CP2_3 and CP2_4. The third DPLL 616 may be routed and/or connected to the third channel groups 611C and 612C via second clock paths CP2_5 and CP2_6. The fourth DPLL 617 may be routed and/or connected to the fourth channel groups 611D and 612D via second clock paths CP2_7 and CP2_8. In an implementation, a first path length of the first clock path CP1 may be greater than a second path length of each of the second clock paths CP2_1 to CP2_8.

FIG. 7 is a diagram showing an example in which a plurality of DPLLs are arranged in a PHY 710 of a base die 700 according to implementations. When describing an implementation of FIG. 7, repeated descriptions as those given above with reference to FIGS. 2, 4, and 6 are omitted.

Referring to FIG. 7, the base die 700 may include the PHY 710, a TSV region 720, a DA region 730, and a TB region 740. The PHY 710 may include first and second channel regions 711 and 712 and a peripheral region 713. At least one DPLL may be included in each of the 32 channels in the first and second channel regions 711 and 712. In an implementation, the first clock path CP1 may form a clock tree having a plurality of branch points to transmit the test clock signal TCK to each of the 32 channels. In an implementation, the peripheral region 713 may include some signal lines of the first clock path CP1 and some first repeaters so that the first clock path CP1 is routed to the first and second channel regions 711 and 712 via the peripheral region 713. However, the configuration of the peripheral region is not limited to the implementation described above. At least one DPLL in each of the channels may be routed, via the second clock path, to various I/O blocks in the channel.

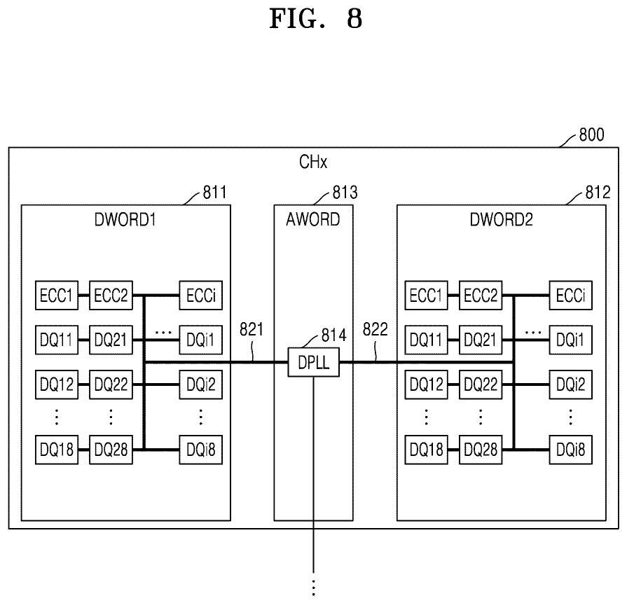

FIG. 8 is a diagram showing an example in which one DPLL 814 is arranged in one channel 800. When describing an implementation of FIG. 8, repeated descriptions as those given above with reference to FIGS. 2, 4, 6, and 7 are omitted.

Referring to FIG. 8, the channel 800 may correspond to any of the 32 channels of FIG. 7. The channel 800 may include at least one data I/O block and a command address block 813. In an implementation, the channel 800 may consist of two pseudo channels. In this case, the channel 800 may include first and second data I/O blocks 811 and 812 as shown in FIG. 8. However, the configuration of the channel is not limited to the example described with reference to FIG. 8. Hereinafter, the channel 800 is assumed to include the first and second data I/O blocks 811 and 812.

Each of the first and second data I/O blocks 811 and 812 may be configured to exchange at least one data signal with a processor. In an implementation, each of the first and second data I/O blocks 811 and 812 may be configured to further receive a data strobe signal from the processor during a write operation. In an implementation, each of the first and second data I/O blocks 811 and 812 may be configured to further transmit a data strobe signal to the processor during a read operation. In an implementation, each of the first and second data I/O blocks 811 and 812 may be configured to receive the output clock signal OCK from the DPLL 814.

Each of the first and second data I/O blocks 811 and 812 may include 1st to ith (error correction code) ECC sub-blocks (see ECC1 to ECCi in FIGS. 8) and 1st to 8th data sub-blocks (see DQ11 to DQ18, DQ21 to DQ28, . . . , and DQi1 to DQi8 in FIG. 8) for each of the ECC sub-blocks. The ECC sub-block may be configured to transmit and receive an ECC data signal. The data sub-block may be configured to transmit and receive a corresponding DQ data signal.

The command address block 813 may be configured to receive a command address signal from the processor. The command address block 813 may include one DPLL 814. The one DPLL 814 may be routed with the first data I/O block 811 via a second clock path 821 and routed with the second data I/O block 812 via a second clock path 822. The second clock paths 821 and 822 may constitute a clock tree in the form of an H-Tree, a fishbone, a mesh, and/or a combination thereof.

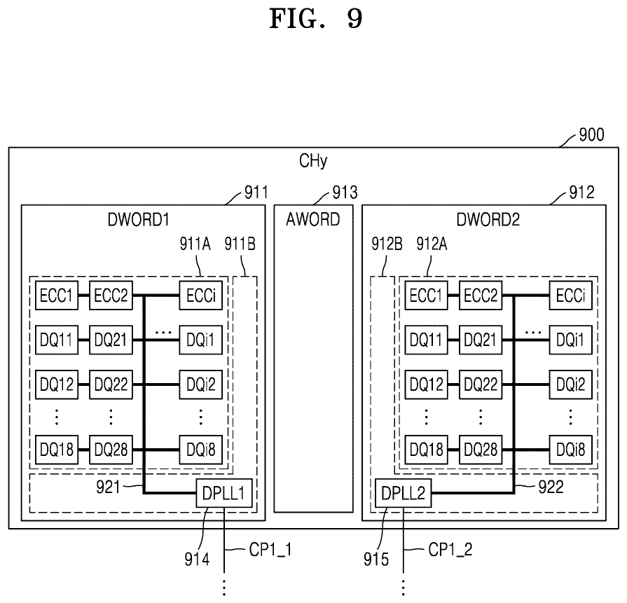

FIG. 9 is a diagram showing an example in which first and second DPLLs 914 and 915 are arranged in one channel 900. When describing an implementation of FIG. 9, repeated descriptions as those given above with reference to FIG. 8 are omitted.

Referring to FIG. 9, the channel 900 may include at least one data I/O block (e.g., first and second data I/O blocks 911 and 912) and a command address block 913.

The first data I/O block 911 may include first and second regions 911A and 911B. The first region 911A may include a plurality of ECC sub-blocks and a plurality of data sub-blocks. The second region 911B may represent a spare region of the first data I/O block 911, other than the first region 911A, and may include the first DPLL 914. In an implementation, the first DPLL 914 may be configured to receive the test clock signal TCK via a first clock path CP1_1 and configured to transmit a first output clock signal to the plurality of ECC sub-blocks and the plurality of data sub-blocks via a second clock path 921.

The second data I/O block 912 may include first and second regions 912A and 912B. The first region 912A may include a plurality of ECC sub-blocks and a plurality of data sub-blocks. The second region 912B may represent a spare region and include the second DPLL 915. In an implementation, the second DPLL 915 may be configured to receive the test clock signal TCK via a first clock path CP1_2 and configured to transmit a second output clock signal to the plurality of ECC sub-blocks and the plurality of data sub-blocks via a second clock path 922. The first and second output clock signals according to an implementation may be the same signal.

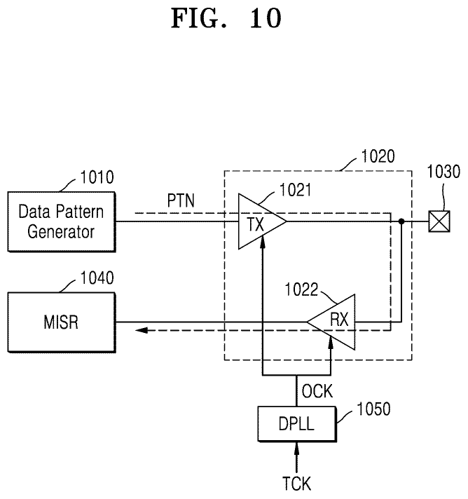

FIG. 10 is a diagram illustrating a testing operation according to implementations.

Referring to FIG. 10, a data pattern generator 1010 may generate a pattern data signal PTN used in the test mode. A data sub-block 1020 is the same as described with reference to FIG. 9. The data sub-block 1020 may include a transmitter 1021 and a receiver 1022. In a state in which the memory device (e.g., 100 in FIG. 1) is packaged, the transmitter 1021 may be synchronized with an edge of an output clock signal OCK and transmit a data signal to a processor via a bump 1030. In a state in which the memory device is packaged, the receiver 1022 may be synchronized with the edge of the output clock signal OCK and receive a data signal via the bump 1030. In the chip-on-wafer state before the memory device (e.g., 100 in FIG. 1) is packaged, the bump 1030 is not connected to an external processor yet. In the test mode in the chip-on-wafer state, the pattern data signal PTN may be provided to a multiple input shift register (MISR) 1040 via the transmitter 1021 and the receiver 1022. In this case, the transmitter 1021 may be synchronized with the edge of the output clock signal OCK and transmit the pattern data signal PTN to the receiver 1022. The receiver 1022 may be synchronized with the edge of the output clock signal OCK and transmit the pattern data signal PTN to the MISR 1040. The MISR 1040 may compare a value of the pattern data signal PTN to a reference value and determine the result of a testing operation based on the comparison result. A DPLL 1050 may receive the test clock signal TCK during the test mode in the chip-on-wafer state and generate the output clock signal OCK based on the test clock signal TCK. The test in the chip-on-wafer state may also be performed on the command address block 913 of FIG. 9, and in this case, the DPLL 1050 may provide the output clock signal OCK based on the test clock signal TCK to the command address block 913.

FIG. 11 is a block diagram of a DPLL 1100 according to implementations.

Referring to FIG. 11, the DPLL 1100 may include a time-to-digital converter (TDC) 1110, a digital loop filter (DLF) 1120, a pulse width modulation (PWM) 1130, a DCO 1140, and a multi-modulus divider (MMD) 1150.

The TDC 1110 may output, as a digital signal UPDN, the difference between a phase of a reference signal FREF and a phase of a feedback signal FFEED. In an implementation, the TDC 1110 may be implemented as a bang-bang phase detector (BBPD). The digital signal UPDN may also be referred to as an up-down signal. For example, when the phase of the feedback signal FFEED leads the phase of the reference signal FREF, the digital signal UPDN may have a first logic level representing “down.” When the phase of the feedback signal FFEED lags behind the phase of the reference signal FREF, the digital signal UPDN may have a second logic level representing “up.” For example, the first logic level of the digital signal UPDN may represent a logic low level, and the second logic level of the digital signal UPDN may represent a logic high level.

The reference signal FREF may correspond to a clock signal generated by an external processor. The reference signal FREF may correspond to the test clock signal TCK generated by an external tester. The feedback signal FFEED may include a signal that is divided from the output signal FOUT by the MMD 1150. The output signal FOUT may correspond to the output clock signal OCK.

The DLF 1120 may provide the DCO 1140 with pieces of digital codes DSIGs to compensate for the phase difference between the phase of the reference signal FREF and the phase of the feedback signal FFEED based on a set target gain. In an implementation, the DLF 1120 may include a proportional path, an integral path, or the like.

The DLF 1120 may receive the feedback signal FFEED from the MMD 1150, and may update a value of an output code for controlling a frequency of the DCO 1140 at every cycle of the feedback signal FFEED based on the digital signal UPDN of the TDC 1110. In addition, the DLF 1120 may receive a k-times feedback signal kFFEED to perform an operation for improving the frequency resolution of the DCO 1140. k may be an integer greater than or equal to 2, and may be set to achieve a relatively small resolution.

The DLF 1120 may generate at least one digital code IKP for adjusting a duty ratio (or a duty cycle) of at least one PWM signal PWM_UP/DN that is generated by the PWM 1130. In an implementation, based on the digital signal UPDN, the DLF 1120 may generate the digital code IKP that adjusts the duty ratio for a first period corresponding to the cycle of the feedback signal FFEED.

The DCO 1140 may adjust the output frequency of the output signal FOUT by changing capacitance of a capacitor bank based on at least one PWM signal PWM_UP/DN. The DCO 1140 may adjust the output frequency of the output signal FOUT based on the digital codes DSIGs and/or at least one PWM signal PWM_UP/DN and may generate the output signal FOUT. In implementations, the DCO 1140 may be implemented as an LC oscillator including an inductor and a capacitor. A negative voltage-current converter may be provided, which has a cross-coupled structure for providing an inductor, a plurality of capacitor banks, and negative resistance. The voltage-current converter according to the present disclosure may be referred to as a transconductance (or gm) cell. The plurality of capacitor banks may provide capacitance based on pieces of digital code or PWM signals. The combined capacitance of the DCO 1140 may vary depending on the capacitance provided by the plurality of capacitor banks, and accordingly, the output frequency may change. In implementations, the plurality of capacitor banks may include some capacitor banks that replace varactors.

The PWM 1130 may generate at least one PWM signal PWM_UP/DN having a duty ratio based on the digital code IKP. In a fine tuning operation of the DPLL 1100, the PWM 1130 may provide the DCO 1140 with at least one PWM signal PWM_UP/DN for tuning the output frequency of the output signal FOUT to a target frequency. For example, the PWM 1130 may provide at least one PWM signal PWM_UP/DN to some capacitor banks that replace varactors among the plurality of capacitor banks, and some capacitor banks may provide capacitors for a period of time corresponding to the duty ratio of the PWM signal. Accordingly, average capacitance during one cycle of the PWM signal may be reflected in the combined capacitance of the DCO 1140. At least one PWM signal PWM_UP/DN may include first and second PWM signals. A signal having a duty ratio of a specific logic level among the first and second PWM signals may be determined according to the logic level of the digital signal UPDN. For example, when the digital signal UPDN is at the first logic level, a first signal PWM_DN may have the duty ratio of the specific logic level. When the digital signal UPDN is at the second logic level, a second signal PWM_UP may have the duty ratio of the specific logic level.

The MMD 1150 may output the feedback signal FFEED by dividing the output signal FOUT. In implementations, the MMD 1150 may output the k-times feedback signal kFFEED.

The DPLL 1100 may further include automatic frequency calibration (AFC) of coarse-tuning the output frequency of the output signal FOUT based on the reference signal FREF and the feedback signal FFEED.

The DPLL 1100 may achieve a small area by processing a loop filter, which is a passive element occupying a large area, as a digital element. Accordingly, the DPLL 1100 may be included in the PHY 111 of the memory device 100.

The DPLL 1100 may be process-insensitive due to being robust to pole/zero variation, leakage, and noise in the loop filter. The DPLL 1100 may have a short turnaround time (TAT) due to ease of testing, calibration, and the like.

According to the implementations described above, the effect of improving power supply rejection ratio (PSRR) characteristics, the effect of improving ultra-low jitter, the effect of improving frequency drift due to changes in temperature, and the effect of improving the quality of service (QoS) of the DCO or the quality factor Q of an LC tank may be achieved.

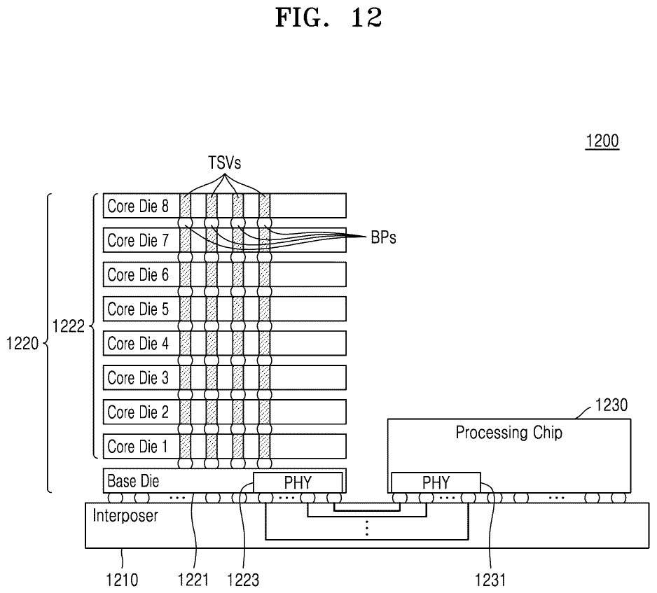

FIGS. 12 to 14 are diagrams showing examples of semiconductor packages according to implementations.

Referring to FIG. 12, a semiconductor package 1200 may include an interposer 1210, a memory device 1220, and a processing chip 1230. The semiconductor package 1200 may further include a substrate that is disposed below the interposer 1210.

The interposer 1210 may include signal lines that connect the memory device 1220 to the processing chip 1230. For example, the interposer 1210 may provide physical paths that include conductive materials and electrically connect a PHY 1223 of the memory device 1220 to a PHY 1231 of the processing chip 1230.

The memory device 1220 may be stacked on the interposer 1210. The memory device 1220 may include a base die 1221 and a plurality of core dies 1222. The memory device 1220 may have a test structure, which may be tested at high speed by a test apparatus, in a chip-on-wafer state before being packaged. FIG. 12 shows that the number of core dies 1222 is eight, but the number of core dies is not limited to the example of FIG. 12. The base die 1221 may be electrically connected to the interposer 1210 via a plurality of microbumps BPs. The base die 1221 may include the PHY 1223, and the PHY 1223 may include the DPLL as described with reference to FIGS. 1 to 11. The plurality of core dies 1222 may be stacked on the base die 1221, a plurality of TSVs TSVs may be formed through the plurality of core dies 1222, and the plurality of microbumps BPs for electrically connecting the plurality of TSVs TSVs to each other may be arranged between the plurality of core dies 1222. The plurality of TSVs TSVs and the plurality of microbumps BPs may provide electrical and physical paths between the base die 1221 and the plurality of core dies 1222. The implementations described above with reference to FIGS. 1 to 11 may be applied to the memory device 1220.

The processing chip 1230 may correspond to processors, such as a system-on-chip, a graphics processing unit (GPU), and a central processing unit (CPU). The processing chip 1230 may include the PHY 1231 that is electrically connected to the PHY 1223 of the base die 1221 via the interposer 1210. The PHY 1231 of the processing chip 1230 may communicate with the PHY 1223 of the base die 1221, and may transmit data signals to or receive data signals from the PHY 1223 of the base die 1221.

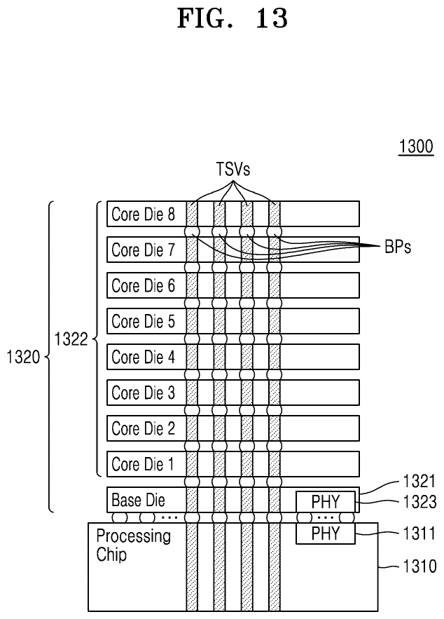

Referring to FIG. 13, a semiconductor package 1300 may include a processing chip 1310 and a memory device 1320 stacked on the processing chip 1310. The memory device 1320 may include a base die 1321 and a plurality of core dies 1322. The memory device 1320 may have a structure that may be tested, in a chip-on-wafer state, at a high speed by a tester. A PHY 1323 of the base die 1321 may include the DPLL described above with reference to FIGS. 1 to 11. A PHY 1311 of the processing chip 1310 may be electrically connected to the PHY 1323 of the base die 1321 via the plurality of microbumps BPs. The processing chip 1310 may further include the plurality of TSVs TSVs that are used to electrically connect the processing chip 1310 to the memory device 1320, and the plurality of TSVs TSVs may be formed through the processing chip 1310. The semiconductor package 1300 may further include an interposer disposed on one surface of the processing chip 1310 (e.g., below the processing chip 1310) and a substrate disposed on one surface of the interposer (e.g., below the interposer).

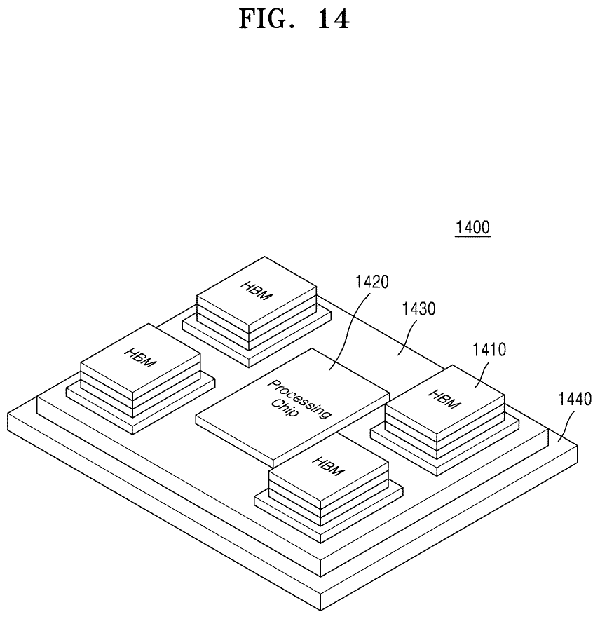

Referring to FIG. 14, the semiconductor package 1400 may include a plurality of HBM devices 1410, a processing chip 1420, an interposer 1430, and a substrate 1440. The semiconductor package 1400 may be used for data processing. For example, the semiconductor package 1400 may be used for neural network computations. A hardware accelerator provided in the semiconductor package 1400 may perform the neural network computations by using data and model weights, and the plurality of HBM devices 1410 may store the data and weights based on control by the hardware accelerator. Each of the plurality of HBM devices 1410 may correspond to the memory device 100 of FIG. 1, and a PHY of a base die in each of the plurality of HBM devices 1410 may include the DPLL described above with reference to FIGS. 1 to 11. The plurality of HBM devices 1410 may have a test structure, which may be tested at high speed by a test apparatus, in a chip-on-wafer state before being packaged. The interposer 1430 may be disposed on the substrate 1440, the plurality of HBM devices 1410 and the processing chip 1420 may be disposed on the interposer 1430, and the plurality of HBM devices 1410 may be stacked on the interposer 1430. According to implementations, the plurality of HBM devices 1410 may perform arithmetic processing. The processing chip 1420 may be implemented as hardware accelerators such as a GPU, a field-programmable gate array (FPGA), a massively parallel processor array (MPPA), an application-specific integrated circuit (ASIC), a neural processing unit (NPU), a tensor processing unit (TPU), and a multi-processor system-on-chip (MPSoC), or as a CPU. The processing chip 1420 may communicate with the plurality of HBM devices 1410 via PHYs. In another implementation, the processing chip 1420 may be omitted from the semiconductor package 1400.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While certain examples have been particularly shown and described, it will be understood that various changes in form and details may be made therein without departing from the spirit and scope of this disclosure.

What is claimed is:

1. A memory device comprising:
a base die and at least one core die,
wherein the base die comprises:
a direct access (DA) region configured to receive a test clock signal via a pad; and
a physical interface (PHY) comprising at least one digital phase-locked loop (DPLL), and
wherein the at least one DPLL is configured to generate an output clock signal by changing capacitance of a capacitor bank of a digitally-controlled oscillator (DCO) based on a pulse width modulation (PWM) signal according to a phase difference between the test clock signal and a feedback signal.

2. The memory device of claim 1, wherein the PHY comprises:
at least one channel region comprising a plurality of channels each comprising the at least one DPLL; and
a peripheral region comprising at least one signal line to transmit the test clock signal.

3. The memory device of claim 2, wherein the plurality of channels comprise:
a first data input/output block comprising a plurality of first data sub-blocks configured to transmit and receive a first data signal to and from a processor and a first DPLL configured to output a first output clock signal to the plurality of first data sub-blocks;
a second data input/output block comprising a plurality of second data sub-blocks configured to transmit and receive a second data signal to and from the processor and a second DPLL configured to output a second output clock signal to the plurality of second data sub-blocks; and
a command address block configured to receive a command address signal from the processor.

4. The memory device of claim 2, wherein the plurality of channels comprise:
at least one data input/output block configured to transmit and receive at least one data signal to and from a processor and configured to receive the output clock signal; and
a command address block configured to receive a command address signal from the processor and comprising the at least one DPLL.

5. The memory device of claim 1, wherein the PHY comprises:
at least one channel region comprising a plurality of channels configured to communicate with a processor and configured to receive the output clock signal; and
a peripheral region comprising the at least one DPLL.

6. The memory device of claim 5, wherein the peripheral region comprises one DPLL connected to the plurality of channels.

7. The memory device of claim 5, wherein the peripheral region comprises:
a first DPLL connected to at least some of the plurality of channels in a first channel region among the at least one channel region; and
a second DPLL connected to at least one channel that is different from the at least some of the plurality of channels in the first channel region.

8. The memory device of claim 1, wherein the base die comprises:
a first clock path having a first path length between the pad and the at least one DPLL and comprising a first repeater group configured to transmit the test clock signal to the at least one DPLL; and
a second clock path having a second path length between the at least one DPLL and at least one data input/output block in the PHY and comprising a second repeater group configured to transmit the output clock signal to the at least one data input/output block.

9. The memory device of claim 8, wherein the first repeater group comprises a plurality of first repeaters connected to each other in series,
wherein the second repeater group comprises a plurality of repeater sub-groups, each comprising a certain number of second repeaters connected to each other in parallel,
wherein a number of first repeaters in the first repeater group is less than a number of second repeaters in the second repeater group, and
wherein the first path length is greater than the second path length.

10. A memory device comprising a base die and at least one core die,
wherein the base die comprises:
a direct access (DA) region configured to receive a test clock signal via a pad; and
a physical interface (PHY) comprising at least one digital phase-locked loop (DPLL) configured to generate an output clock signal based on the test clock signal, and
wherein the at least one DPLL comprises:
a time-to-digital converter (TDC) configured to convert a phase difference between the test clock signal and a feedback signal into a digital signal;
a digital loop filter (DLF) configured to, based on the digital signal, generate a digital code to adjust a duty ratio for a first period corresponding to a cycle of the feedback signal;
a pulse width modulation (PWM) configured to, based on the digital code, generate a PWM signal having the duty ratio;
a digitally-controlled oscillator (DCO) configured to adjust an output frequency of the output clock signal by changing capacitance of a capacitor bank based on the PWM signal; and
a divider configured to generate the feedback signal by dividing the output clock signal.

11. The memory device of claim 10, wherein the PHY comprises:
at least one channel region comprising a plurality of channels each comprising the at least one DPLL; and
a peripheral region comprising at least one signal line for transmitting the test clock signal.

12. The memory device of claim 11, wherein the plurality of channels comprise:
a first data input/output block comprising a plurality of first data sub-blocks configured to transmit and receive a first data signal to and from a processor and a first DPLL configured to output a first output clock signal to the plurality of first data sub-blocks;
a second data input/output block comprising a plurality of second data sub-blocks configured to transmit and receive a second data signal to and from the processor and a second DPLL configured to output a second output clock signal to the plurality of second data sub-blocks; and
a command address block configured to receive a command address signal from the processor.

13. The memory device of claim 11, wherein the plurality of channels comprise:
at least one data input/output block configured to transmit and receive at least one data signal to and from a processor and configured to receive the output clock signal; and
a command address block configured to receive a command address signal from the processor and comprising the at least one DPLL.

14. The memory device of claim 10, wherein the PHY comprises:
at least one channel region comprising a plurality of channels configured to communicate with a processor and configured to receive the output clock signal; and
a peripheral region comprising the at least one DPLL.

15. The memory device of claim 10, wherein the base die comprises:
a first clock path having a first path length between the pad and the at least one DPLL and comprising a first repeater group configured to transmit the test clock signal to the at least one DPLL; and
a second clock path having a second path length between the at least one DPLL and at least one data input/output block in the PHY and comprising a second repeater group configured to transmit the output clock signal to the at least one data input/output block.

16. A semiconductor package comprising:
a substrate;
at least one memory device on the substrate and comprising a base die and at least one core die; and
a processing chip on the substrate and configured to output a clock signal to the base die,
wherein the base die comprises:
a physical interface (PHY) comprising at least one digital phase-locked loop (DPLL) configured to generate an output clock signal by changing capacitance of a capacitor bank of a digitally-controlled oscillator (DCO) based on a pulse width modulation (PWM) signal according to a phase difference between the clock signal and a feedback signal; and
a through silicon via (TSV) region configured to communicate with the at least one core die.

17. The semiconductor package of claim 16, wherein the PHY comprises:
at least one channel region comprising a plurality of channels each comprising the at least one DPLL; and
a peripheral region comprising at least one signal line for transmitting the clock signal.

18. The semiconductor package of claim 17, wherein the plurality of channels comprise:
a first data input/output block comprising a plurality of first data sub-blocks configured to transmit and receive a first data signal to and from the processing chip and a first DPLL configured to output a first output clock signal to the plurality of first data sub-blocks;
a second data input/output block comprising a plurality of second data sub-blocks configured to transmit and receive a second data signal to and from the processing chip and a second DPLL configured to output a second output clock signal to the plurality of second data sub-blocks; and
a command address block configured to receive a command address signal from the processing chip.

19. The semiconductor package of claim 17, wherein the plurality of channels comprise:
at least one data input/output block configured to transmit and receive at least one data signal to and from the processing chip and configured to receive the output clock signal; and
a command address block configured to receive a command address signal from the processing chip and comprising the at least one DPLL.

20. The semiconductor package of claim 16, wherein the PHY comprises:
at least one channel region comprising a plurality of channels configured to communicate with the processing chip and configured to receive the output clock signal; and
a peripheral region comprising the at least one DPLL.
